(19) United States
(12) Patent Application Publication
(10) Pub. No.: US 2025/0089201 A1
(43) Pub. Date: Mar. 13, 2025

(54) RECESSED POWER CABLE TRANSITION PANEL

(71) Applicant: CommScope Technologies LLC, Claremont, NC (US)

(72) Inventors: Mark G. Spaulding, Wylie, TX (US); John P. Higgins, Dallas, TX (US); Wayne C. Hopkinson, Hickory, NC (US)

(21) Appl. No.: 18/957,155

(22) Filed: Nov. 22, 2024

Related U.S. Application Data
(63) Continuation of application No. PCT/US2023/023274, filed on May 23, 2023.
(60) Provisional application No. 63/345,927, filed on May 26, 2022.

(51) Int. Cl. H05K 7/14

(52) U.S. Cl. CPC H05K 7/1489; H05K 7/14324; H05K 7/1492

(57) ABSTRACT

A mounting plate supports a connection module for attachment to a pair of first and second network rack rails. The connection module is supported within a window formed within the plate, such that a rear portion of the connection module extends away from a rear face of the plate to a first degree, and a front portion of the connection module is approximately flush with the front face of the plate, or at least extends away from the front face of the plate to a second degree, less than the first degree. The plate may be formed of a single piece of flat metal with the front face and the rear face, left/right side edges, and top/bottom edges. First and second ears and locking tabs, may be bent away from edges of the window within the plate to facilitate support for the connection module.

This application is a continuation of International Application No. PCT/US2023/023274, filed May 23, 2023, which claims the benefit of U.S. Provisional Application No. 63/345,927, filed May 26, 2022, both of which are herein incorporated by reference.

### BACKGROUND OF THE INVENTION

### 1. Field of the Invention

The present invention relates to a panel or plate for mounting a connection module in a network rack. More particularly, the present invention relates to a mounting plate, which allows the connection module to be recessed in the mounting plate to a substantially flush position with respect to a front face of the mounting plate, while providing a sturdy mounting structure which is inexpensive to fabricate and easy to install.

### 2. Description of the Background

Mounting plates to attach electrical and/or optical connection modules to a network rack are known in the prior art. The typical network rack includes first and second network rack rails which are spaced nineteen to twenty-one inches apart. The mounting plate is a generally flat rectangular plate and is attached to the first and second rack rails and extends between the first and second network rack rails. One or more windows are formed within the mounting plate and one or more features surround each window to secure a connection module within the window.

For example, FIG. 1 shows a mounting plate 12 in accordance with the prior art of U.S. Pat. No. 7,488,205, which is owned by the current assignee and is herein incorporated by reference. The mounting plate 12 includes left and right sides 18 and 18A with two mounting openings 19 proximate each of the left and right sides 18 and 18A. The openings 19 accept fasteners 7 to secure the left and right sides 18 and 18A to left and right network rack rails 5 and 5A. Four windows 15-1, 15-2, 15-3 and 15-4 are formed in the mounting plate 12 with notched stanchions defining the lateral sides of the windows 15. The notches accept snap features of the modules to be mounted to the plate 12. Other designs of mounting plates, which are used to attached connection modules to network rack rails, can be found in U.S. Pat. Nos. 6,347,715; 6,537,106 and 6,974,348, which are herein incorporated by reference.

A known type of connection unit 21 is a feed-through terminal block sold under Model No. 3211776 by Phoenix Contact of Middletown, PA. The connection unit 21 is used to electrically connect one end of a first electrical wire to another end of a second electrical wire. As shown in FIG. 2, the Model No. 3211776 connection units 21 can be stacked into an array between first and second end caps 23 and 25 to form a termination block or connection module 27 to connect respective ends of forty-eight electrical wires in a first set to respective ends of forty-eight electrical wires in a second set. Groups of eight connection units 21 may be separated by divider plates 29 within the connection module 27.

Each connection unit 21 includes a first push-in receptacle 31 in a front face of the connection unit 21 near a top 32 of the connection unit 21 to receive an end of an electrical wire of the first set. Each connection unit 21 also includes a second push-in receptacle 33 in the front face of the connection unit 21 near a bottom 34 of the connection unit 21 to receive an end of an electrical wire of the second set. Jumper slots, test ports and/or labels may be provided in or on the front face of the connection unit 21 between the first and second push-in receptacles 31 and 33.

A galvanized steel DIN rail 35 has first and second off-set flanges 37 and 39 along its longitudinal edges. Equally spaced oval openings 41 are formed along a middle line between the first and second off-set flanges 37 and 39. The first and second off-set flanges 37 and 39 of the rail 35 are slid into first and second guide channels 43 and 45 formed on a rear face of the connection units 21, the divider plates 29 and/or the first and second end caps 23 and 25.

The connection module 27 may be slid to a desired location longitudinally along the rail 35. The longitudinal length of the rail 35 is about nineteen to twenty-one inches between first and second lateral ends 47 and 49, so that the rail 35 may be attached to the left and right network rack rails 5 and 5A of FIG. 1 by passing fasteners 7 though the oval openings 41 proximate the first and second lateral ends 47 and 49 of the rail 35.

A particularly safe way to transfer high voltage power from a source to a destination is under development and will be known as digital voltage or class 4 power. Class 4 power sends rapid pulses of high voltage DC current, e.g., 400 volts. The destination receives the pulses, which may be reduced due to some voltage drop over a long transmission line. The destination has equipment to convert the received DC voltage pulses into a new supply voltage which is suitable for the equipment at the destination, e.g., a 240 volt or 120 volt AC signal or a 12, 24 or 48 volt DC signal. If any irregularity occurs in the pulses between the source and destination, e.g., due to an intermittent short or open circuit condition, the source immediately, e.g. within a few milliseconds, stops sending the high voltage DC voltage pulses to avoid an unsafe condition.

Several background art references show systems for providing safe, high voltage pulses, e.g., exceeding 300 VDC. Such background art can be found in U.S. Pat. Nos. 8,781,637; 9,184,795; 9,419,436; 9,853,689; 9,893,521; 10,468,879; 10,541,543 and 10,714,930, and in US Published Application Nos. 2017/0229886; 2018/0313886; 2020/0295559 and 2021/0063447, which are owned by VoltServer of East Greenwich, Rhode Island, and are herein incorporated by reference.

In the class 4 power systems, a source unit that produces the pulses of high voltage DC current has plural electronic transmission cards, e.g., four transmission cards, which each have first and second output terminals. A destination unit that receives the high voltage DC current has plural electronic reception cards, e.g., four reception cards, which each have first and second input terminals.

The source unit may be mounted to the left and right network rack rails 5 and 5A. The connection module 27 of FIGS. 2 and 3 can also be mounted to the left and right network rack rails 5 and 5A. The connection module 27 is well suited to electrically connect jumper wires from the transmission cards of one or more source units to electrical wires at first ends of one or more transmission cables, which carry the power to one or more destination units.

### SUMMARY OF THE INVENTION

The applicant has appreciated drawbacks with the designs of the connection modules and mounting plates of the prior art.

One drawback is that the connection module 27 created by stacking the Model No. 3211776 connection units 21 extends forwardly from the rail 35 because the first and second guide channels 43 and 45 are formed on the rear face of the connection units 21. When the rail 35 is connected to the left and right network rack rails 5 and 5A, the front face of the connection module 27 protrudes away from a plane of the left and right network rack rails 5 and 5A. Hence, the top 32 of the connection module 27 extends forward like a shelf to collect dust and debris.

Further, the height of the connection module 27 is about 2.2 inches, whereas the height of the rail 35 is about 1.2 inches. Therefore, gaps are formed to the lateral sides of the connection module 27 when it is mounted to the left and right network rack rails 5 and 5A. The gaps allow visibility to the wires and cabling inside and behind the network rack and do not present a clean and organized appearance.

Also, the extended length of the rail 35 to the left side is subject to flexure, e.g., bending, when a wire ends are pushed into the first and second push-in receptacles 31 and 33, and/or when jumpers/fuses and testing probes are inserted into the jumper slots and test ports on the front face of the connector module 27.

It is an object of the present invention to address the drawbacks appreciated above. It is an object to provide a stronger mounting system for the connector module 27, which is less susceptible to flexure during wiring and testing operations. It is a further object of the present invention to provide a mounting system for the connector module 27, which moves the front face of the connection module 27 rearwardly to a more flush, if not substantially or fully flush, position relative to the left and right network rack rails 5 and 5A. Moreover, it is an object of the present invention to provide a mounting system for the connector module 27, which closes gaps and improves the appearance of connector module 27 within the network rack by presenting a more integrated and solid structure.

These and other objectives are accomplished by a mounting plate which supports a connection module for attachment to a pair of first and second network rack rails. The connection module is supported within a window formed within the mounting plate, such that a rear portion of the connection module extends away from a rear face of the mounting plate to a first degree, and a front portion of the connection module is approximately flush with the front face of the mounting plate, or at least extends away from the front face of the mounting plate to a second degree, less than the first degree. The mounting plate may be formed of a single piece of flat metal with the front face and the rear face, left/right side edges, and top/bottom edges. First and second ears and locking tabs, may be bent away from edges of the window within the mounting plate to facilitate support for the connection module.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

For a better understanding of the invention, and to show how the same may be carried into effect, reference will now be made, by way of example, to the accompanying drawings, in which:

FIG. 1 is a front, right side perspective view of a network rack and mounting plate, in accordance with the prior art;

FIG. 2 is a front view of a connection module and mounting rail, in accordance with the prior art;

FIG. 3 is a rear, left side perspective view of the connection module and mounting rail of FIG. 2;

FIG. 4 is a front, right side perspective view of a mounting plate, in accordance with the present invention;

FIG. 5 is a rear, left side perspective view of the mounting plate of FIG. 4;

FIG. 6 is a front view of the mounting plate of FIG. 4;

FIG. 7 is a rear view of the mounting plate of FIG. 4;

FIG. 8 is a top view of the mounting plate of FIG. 4;

FIG. 9 is a bottom view of the mounting plate of FIG. 4;

FIG. 10 is a right side view of the mounting plate of FIG. 4;

FIG. 11 is a front view of the connection module of FIGS. 2 and 3 assembled to the mounting plate of FIGS. 4-10;

FIG. 12 is a front, right side perspective view of the assembly of FIG. 11;

FIG. 13 is a closeup, rear, left side perspective view of a mounting plate, similar to the mounting plate of FIGS. 4-10, but illustrating a threaded insert attached to a locking tab and also folded back edges to strengthen the mounting plate; and

FIG. 14 is a rear, left side perspective view of the connection module of FIGS. 2 and 3 assembled to the mounting plate of FIG. 13.

### DETAILED DESCRIPTION OF EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity. Broken lines illustrate optional features or operations unless specified otherwise.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

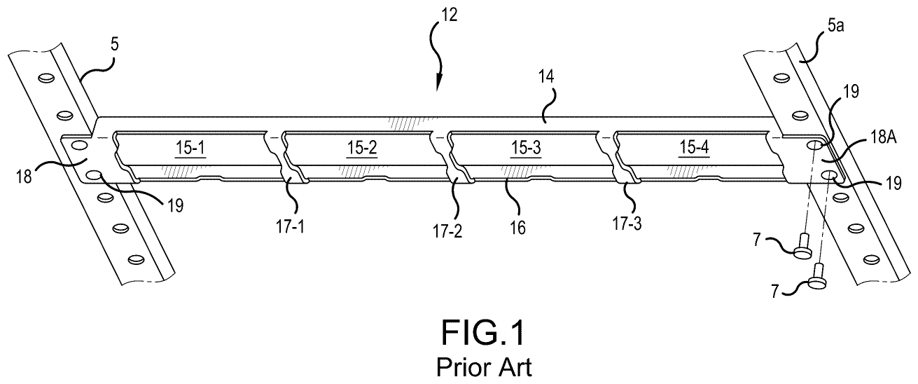

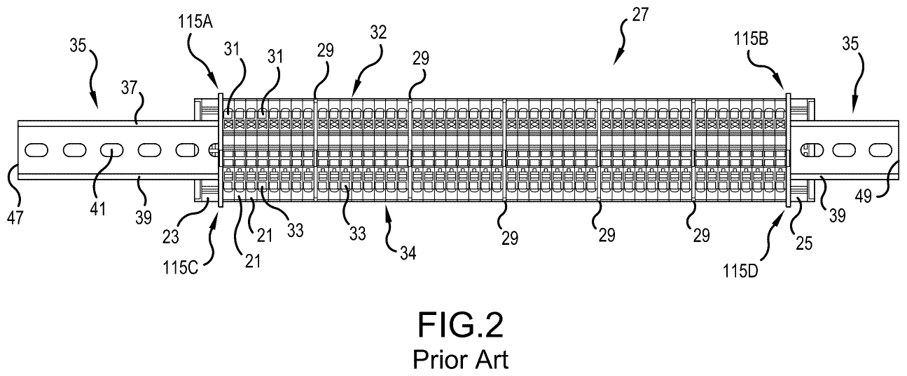

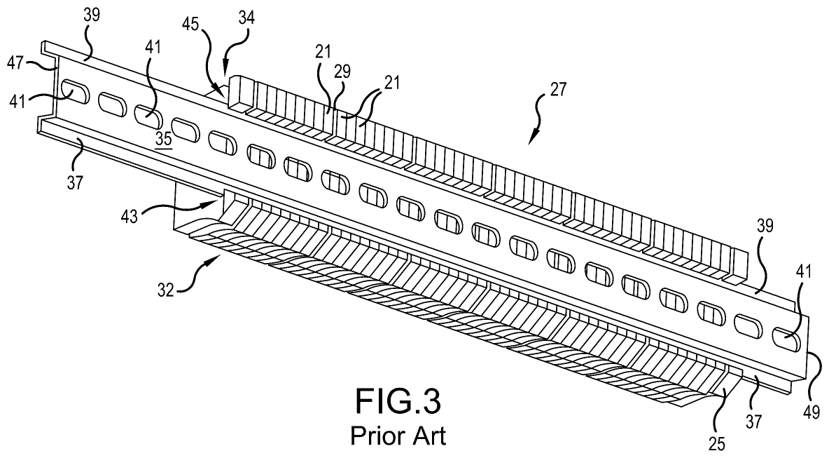

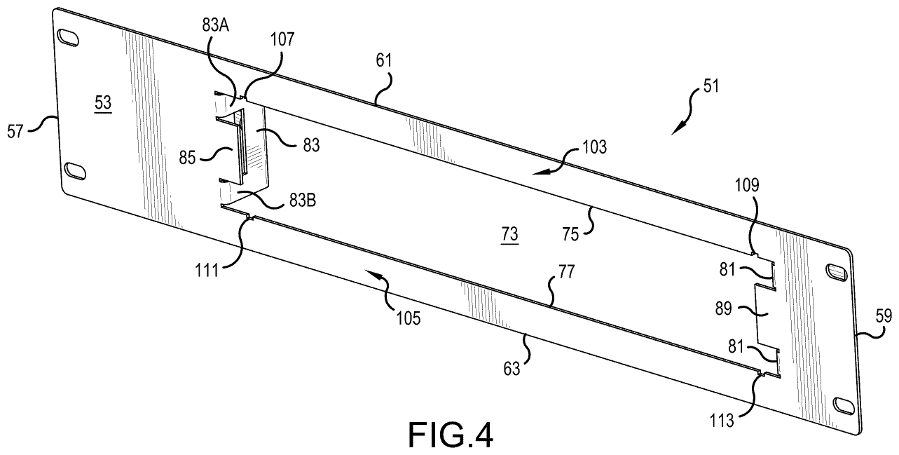

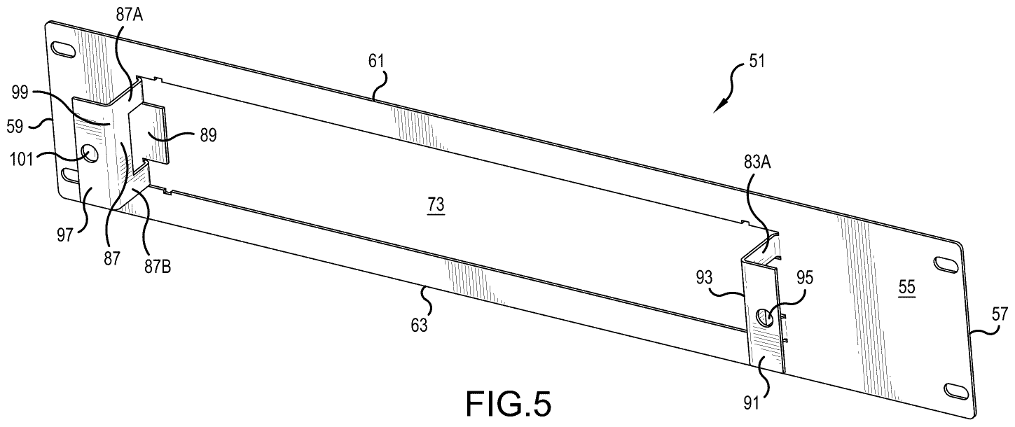

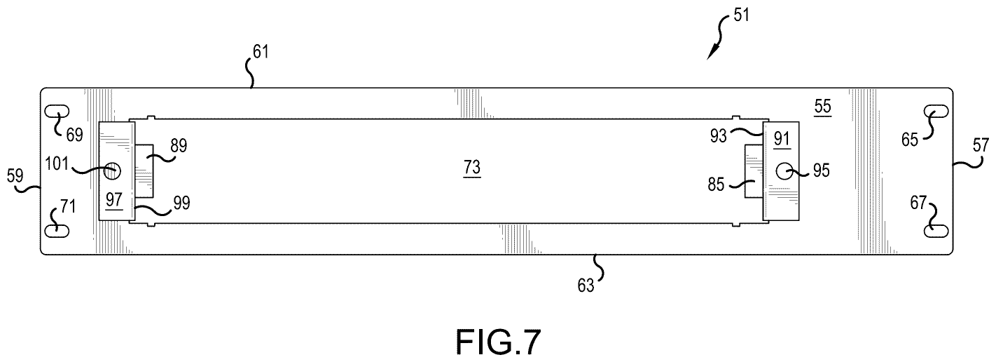

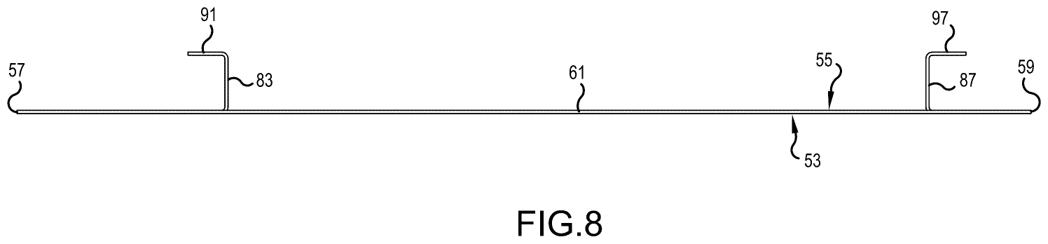

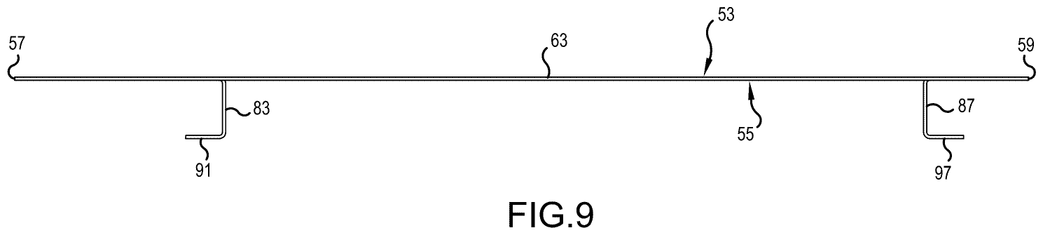

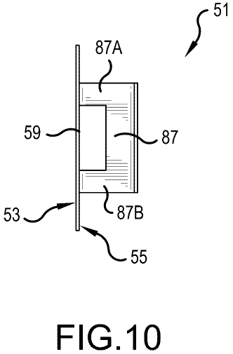

FIGS. 4-10 are various views of a mounting plate 51, in accordance with the present invention. The mounting plate 51 is configured to be attached to a pair of first and second network rack rails, such as the left and right network rack rails 5 and 5A of FIG. 1. Further, the mounting plate 51 is configured to support a connection module, such as the connection module 27 of FIGS. 2-3 with a shortened rail 35.

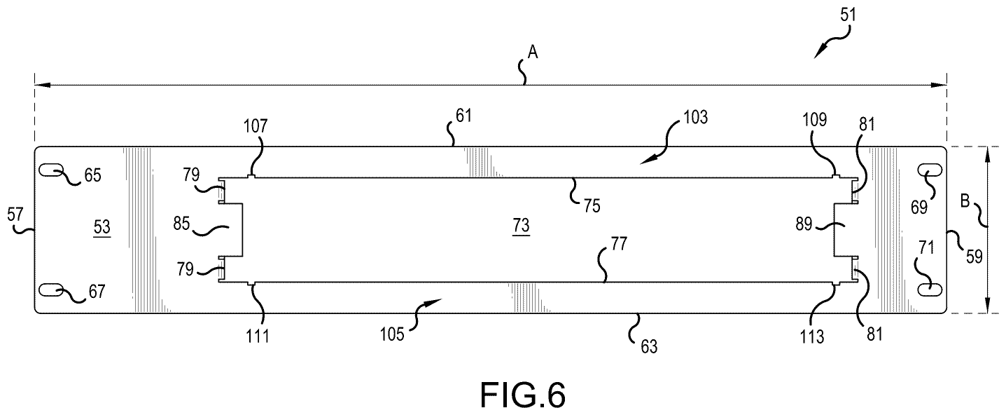

The mounting plate 51 is formed as a generally flat plate having a front face 53 and a rear face 55. The mounting plate 51 has a generally rectangular perimeter defined by first/left and second/right side edges 57 and 59, a top edge 61 and a bottom edge 63. As shown in FIG. 6, a first distance A between the first side edge 57 of the mounting plate 51 and the second side edge 59 of the mounting plate 51 is approximately nineteen to twenty-one inches, such as about nineteen inches. A second distance B between the top edge 61 and the bottom edge 63 is approximately three to four inches, such as about three and a half inches. The mounting plate 51 may be stamped out of a 0.06 inch thick galvanized steel sheet, or other materials known in the art.

At least one first fastening feature is formed on the mounting plate 51 proximate the left side edge 57 for attaching the left side edge 57 to the first network rack rail, such as the left network rack rail 5 of FIG. 1. In a preferred embodiment, the at least one first fastening feature includes first and second oval-shaped openings 65 and 67 formed through the mounting plate 51 proximate the left side edge 57 for accepting first and third fasteners, respectively, such as screws, bolts, pins or clips. At least one second fastening feature is formed on the mounting plate 51 proximate the right side edge 59 for attaching the right side edge 59 to the second network rack rail, such as the right network rack rail 5A of FIG. 1. In a preferred embodiment, the at least one second fastening feature includes third and fourth oval-shaped openings 69 and 71 formed through the mounting plate 51 proximate the right side edge 59 for accepting second and fourth fasteners, respectively, such as screws, bolts, pins or clips.

A window 73 is formed within the mounting plate 51 for supporting the connection module 27. The window 73 is defined within first and second longitudinal edges 75 and 77 and between first and second lateral edges 79 and 81 formed within the front face 53. A first ear 83 extends away from the rear face 55 of the mounting plate 51. The first ear 83 may include first and second legs 83A and 83B with first ends integrally formed with the mounting plate 51. A first tab 85 resides between the first and second legs 83A and 83B and is coplanar with the front face 53 and extends into the window 73. First bends at a juncture of the mounting plate 51 and the first and second legs 83A and 83B of the first ear 83 define the first lateral edge 79. The first ear 83 extends away from the first lateral edge 79 of the window 73 at an angle of about ninety degrees relative to a plane of the front face 53.

A second ear 87 extends away from the rear face 55 of the mounting plate 51. The second ear 87 may include third and fourth legs 87A and 87B with first ends integrally formed with the mounting plate 51. A second tab 89 resides between the third and fourth legs 87A and 87B and is coplanar with the front face 53 and extends into the window 73. First bends at a juncture of the mounting plate 51 and the third and fourth legs 87A and 87B of the second ear 87 define the second lateral edge 81. The second ear 87 extends away from the second lateral edge 81 of the window 73 at an angle of about ninety degrees relative to a plane of the front face 53.

A first locking tab 91 extends away from the first ear 83 for attaching to the connection module 27. The first locking tab 91 is integrally formed with the first ear 83. A third bend 93 at a juncture of the first ear 83 and the first locking tab 91 causes the first locking tab 91 to extend at an angle of about ninety degrees away from the first ear 83. The first locking tab 91 includes a first through hole 95 therein for receiving a first element, such as a bolt, screw, clip or pin, for attaching the first locking tab 91 to the connection module 27.

Likewise, a second locking tab 97 extends away from the second ear 87 for attaching to the connection module 27. The second locking tab 97 is integrally formed with the second ear 87. A fourth bend 99 at a juncture of the second ear 87 and the second locking tab 97 causes the second locking tab 97 to extend at an angle of about ninety degrees away from the second ear 87. The second locking tab 97 includes a second through hole 101 therein for receiving a second element, such as a bolt, screw, clip or pin, for attaching the second locking tab 97 to the connection module 27.

As best seen in FIGS. 4-7, the window 73 is offset to be closer to the right side edge 59, as compared to the left side edge 57, of the mounting plate 51. The offset alignment of the window 73 may assist in placing the connection module 27 closer to the transmission cards of the source unit providing class 4 power, as mentioned in the discussion of the background art above. In a preferred embodiment, the window 73 is equally distanced between said top and bottom edges 61 and 63 of the mounting plate 51. This arrangement provides a first labeling surface 103 located above the window 73 and a second labeling surface 105 located below the window 73 on the front face 53 of the mounting plate 51.

First and second notches 107 and 109 may optionally be formed through the mounting plate 51 along the first longitudinal edge 75 of the window 73. As best seen in FIG. 6, the first notch 107 is located adjacent to a junction between the first longitudinal edge 75 and the first lateral edge 79 of the window 73, and the second notch 109 is located adjacent to a junction between the first longitudinal edge 75 and the second lateral edge 81 of the window 73. Likewise, third and fourth notches 111 and 113 may optionally be formed through the mounting plate 51 along the second longitudinal edge 77 of the window 73. As best seen in FIG. 6, the third notch 111 is located adjacent to a junction between the second longitudinal edge 77 and the first lateral edge 79 of the window 73, and the fourth notch 113 is located adjacent to a junction between the second longitudinal edge 77 and the second lateral edge 81 of the window 73.

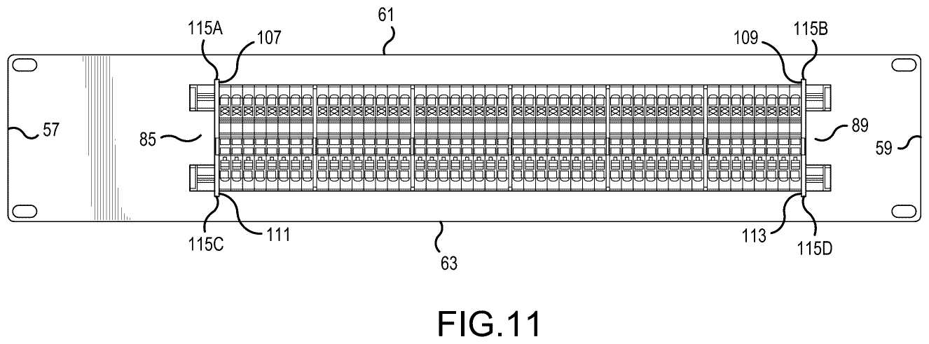

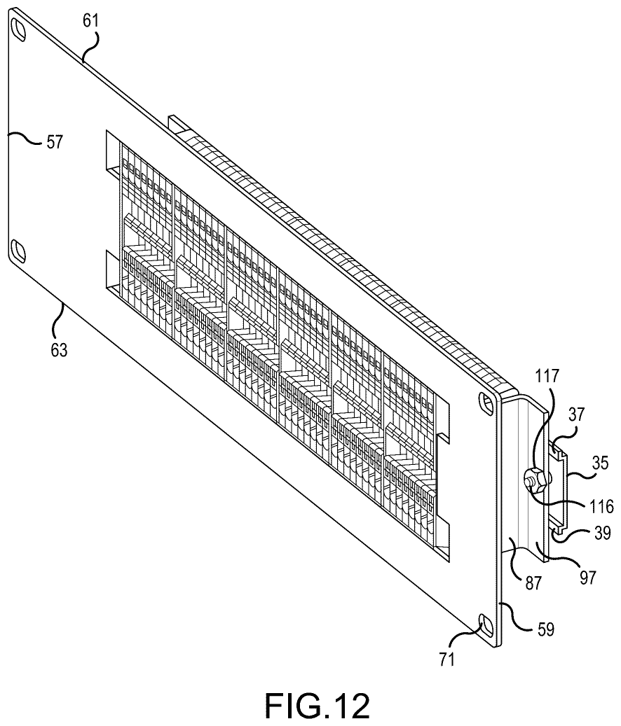

As best seen in FIG. 2, the first and second end caps 23 and 25 of the connection module 27 include first and second blades 115A and 115B at the top 32 of the connection module 27. The first and second end caps 23 and 25 of the connection module 27 also include third and fourth blades 115C and 115D at the bottom 34 of the connection module 27. As shown in FIG. 11, the first, second, third and fourth blades 115A, 115B, 115C and 115D may seat into or pass through the first, second, third and fourth notches 107, 109, 111 and 113, respectively, when the front face of the connection module 27 is placed into the window 73. Alternatively, as shown in FIG. 12, the first, second, third and fourth notches 107, 109, 111 and 113 may be omitted from the mounting plate 51 and the first, second, third and fourth blades 115A, 115B, 115C and 115D may abut against the rear face 55 of the mounting plate 51, adjacent to the first and second longitudinal edges 75 and 77.

FIG. 12 also shows the second element passing through the second through hole 101 being in the form of a screw or bolt. A head of the screw or bolt abuts edges of one of the oval openings 41 of the rail 35. A threaded shank 116 of the screw or bolt passes through the oval opening 41 of the rail 35 and the second through hole 101. A nut 117 is engaged and tightened to the threaded shank 116 and abuts the second locking tab 97.

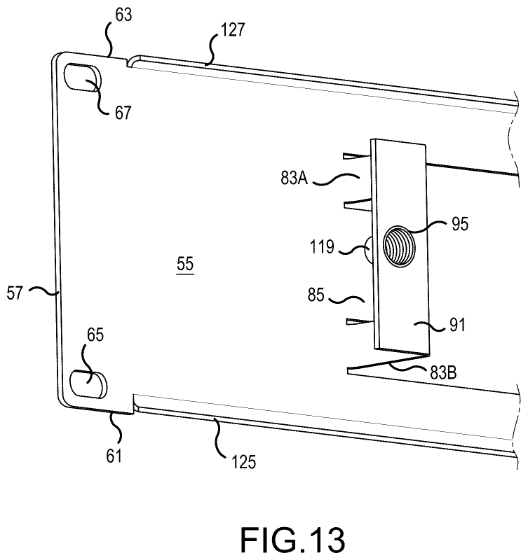

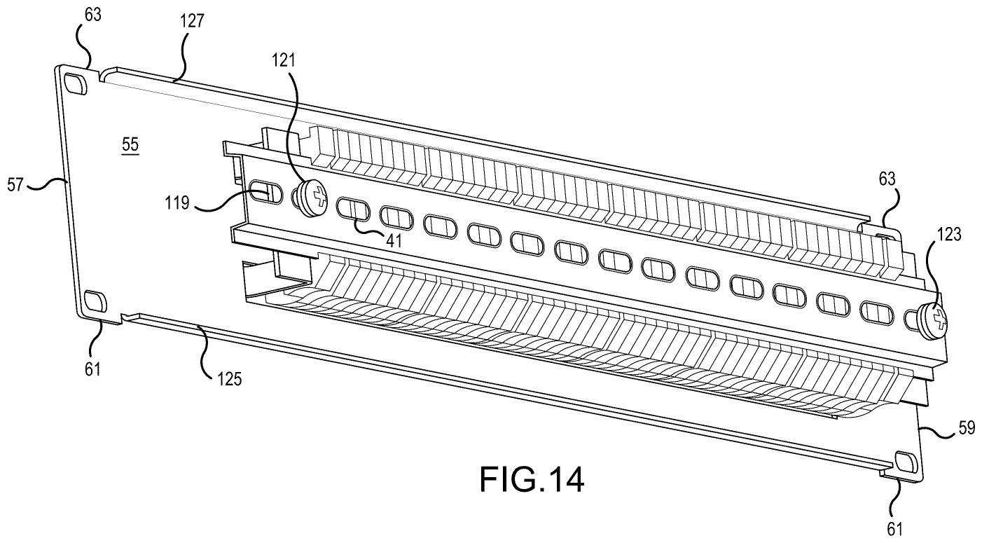

FIG. 13 shows an alternative embodiment wherein a first threaded insert 119 may optionally be attached within or to the first through hole 95 and replaces the nut 117 of FIG. 12. The first threaded insert 119 may sometimes be called a blind rivet nut, clinch nut or sold under the trademark RIVNUT®. In a preferred embodiment, the first threaded insert 119 may have a thread gauge of M6 and be adapted to engage a correspondingly sized first threaded bolt or screw 121, as shown in FIG. 14. The first threaded bolt or screw 121 would be passed through one of the oval openings 41 of the rail 35 and then tightened into the first threaded insert 119. Of course, an identical second threaded insert would be attached within or to the second through hole 101 and sized to engage with an identical second threaded bolt or screw 123.

FIGS. 13 and 14 also show an optional rigidity enhancement for the mounting plate 51. The top edge 61 of the mounting plate 51 includes a first turned-back extension 125, which extends away from the rear face 55 of the mounting plate 57, at an angle of about sixty to one hundred degrees, to provide rigidity to the top edge 61. Likewise, the bottom edge 63 of the mounting plate 57 includes a second turned-back extension, 127 which extends away from the rear face 55 of the mounting plate 57, at an angle of about sixty to one hundred degrees, to provide rigidity to the bottom edge 63 of the mounting plate 57.

As shown in FIGS. 12 and 14, the connection module 27 securely resides within the window 73. A rear portion of the connection module 27 extends away from the rear face 55 of the mounting plate 51 to a first degree. A front face or portion of the connection 27 module is approximately flush with the front face 53 of the mounting plate 51 or extends away from the front face 53 of the mounting plate 51 to a second degree, less than the first degree.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

We claim:

1. A mounting plate for attaching to a pair of first and second network rack rails and for supporting a connection module, said mounting plate comprising:
a generally flat plate having a front face and a rear face, left and right side edges, a top edge and a bottom edge;
at least one first fastening feature formed on said plate proximate said left side edge for attaching said left side edge to the first network rack rail;
at least one second fastening feature formed on said plate proximate said right side edge for attaching said right side edge to the second network rack rail;
a window formed within said mounting plate for supporting the connection module, said window being defined within first and second longitudinal edges and first and second lateral edges formed within said front face;
a first ear extending away from said rear face of said mounting plate;
a second ear extending away from said rear face of said mounting plate;
a first locking tab extending away from said first ear for attaching to the connection module; and
a second locking tab extending away from said second ear for attaching to the connection module.

2. The mounting plate according to claim 1, wherein said first ear extends away from said first lateral edge of said window at an angle of about ninety degrees; and wherein said second ear extends away from said second lateral edge of said window at an angle of about ninety degrees.

3. The mounting plate according to claim 2, wherein said first ear is integrally formed with said mounting plate and a first bend at a juncture of said mounting plate and said first ear causes said first ear to extend at said angle of about ninety degrees away from said rear face of said mounting plate; and wherein said second ear is integrally formed with said mounting plate and a second bend at a juncture of said mounting plate and said second ear causes said second ear to extend at said angle of about ninety degrees away from said rear face of said mounting plate.

4. The mounting plate according to claim 3, wherein said first locking tab is integrally formed with said first ear and a third bend at a juncture of said first ear and said first locking tab causes said first locking tab to extend at an angle of about ninety degrees away from said first ear; and wherein said second locking tab is integrally formed with said second ear and a fourth bend at a juncture of said second ear and said second locking tab causes said second locking tab to extend at an angle of about ninety degrees away from said second ear.

5. The mounting plate according to claim 1, wherein said first locking tab includes a first through hole therein for receiving a first element for attaching said first locking tab to the connection module; and wherein said second locking tab includes a second through hole therein for receiving a second element for attaching said second locking tab to the connection module.

6. The mounting plate according to claim 5, further comprising:
a first threaded insert attached within or to said first through hole, wherein said first element is a threaded bolt or screw to engage said first threaded insert; and
a second threaded insert attached within or to said second through hole, wherein said second element is a threaded bolt or screw to engage said second threaded insert.

7. The mounting plate according to claim 1, wherein a distance between said first edge of said mounting plate and said second edge of said mounting plate is approximately nineteen to twenty-one inches.

8. The mounting plate according to claim 1, wherein said at least one first fastening feature is a first opening formed through said mounting plate proximate said left edge for accepting a first fastener therethrough; and wherein said at least one second fastening feature is a second opening formed through said mounting plate proximate said right edge for accepting a second fastener therethrough.

9. The mounting plate according to claim 1, wherein said at least one first fastening feature includes first and second openings formed through said mounting plate proximate said left edge for accepting first and third fasteners, respectively; and wherein said at least one second fastening feature includes third and fourth openings formed through said mounting plate proximate said right edge for accepting second and fourth fasteners, respectively.

10. The mounting plate according to claim 1, wherein said window is offset to be closer to said right side edge of said mounting plate.

11. The mounting plate according to claim 10, wherein said window is equally distanced between said top and bottom edges of said mounting plate; and further comprising:
a first labeling surface located above said window on said front face of said mounting plate; and
a second labeling surface located below said window on said front face of said mounting plate.

12. The mounting plate according to claim 1, further comprising:
first and second notches formed through said mounting plate along said first longitudinal edge of said window; and
third and fourth notches formed through said mounting plate along said second longitudinal edge of said window, wherein said first notch is located adjacent to a junction between said first longitudinal edge and said first lateral edge of said window, and wherein said third notch is located adjacent to a junction between said first longitudinal edge and said second lateral edge of said window, and wherein said third notch is located adjacent to a junction between said second longitudinal edge and said first lateral edge of said window, and wherein said fourth notch is located adjacent to a junction between said second longitudinal edge and said second lateral edge of said window.

13. The mounting plate according to claim 1, wherein said top edge of said mounting plate includes a first turned-back extension, which extends away from said rear face of said mounting plate to provide rigidity to said top edge of said mounting plate, and wherein said bottom edge of said mounting plate includes a second turned-back extension, which extends away from said rear face of said mounting plate to provide rigidity to said bottom edge of said mounting plate.

14. A combination of a connection module and a mounting plate for attachment to a pair of first and second network rack rails, said combination comprising:
a generally flat plate having a front face and a rear face, left and right side edges, a top edge and a bottom edge;
at least one first fastening feature formed on said plate proximate said left side edge for attaching said left side edge to the first network rack rail;
at least one second fastening feature formed on said plate proximate said right side edge for attaching said right side edge to the second network rack rail;
a window formed within said mounting plate, said window being defined within first and second longitudinal edges and first and second lateral edges formed within said front face;
a connection module located within said window having a rear portion of said connection module extending away from said rear face of said mounting plate to a first degree, and a front portion of said connection module being approximately flush with said front face of said mounting plate or extending away from said front face of said mounting plate to a second degree less than said first degree;
a first ear extending away from said rear face of said mounting plate;
a second ear extending away from said rear face of said mounting plate;
a first locking tab extending away from said first ear attached to said connection module; and
a second locking tab extending away from said second ear attached to said connection module.

15. The combination according to claim 14, wherein said first locking tab includes a first through hole therein and a first threaded insert attached within or to said first through hole, and wherein said second locking tab includes a second through hole therein and a second threaded insert attached within or to said second through hole, and further comprising:
a first threaded bolt or screw passing through a portion of said connection module or a fixture of said connection module to engage said first threaded insert and attach said connection module to said first locking tab; and
a second threaded bolt or screw passing through a portion of said connection module or a fixture of said connection module to engage said second threaded insert and attach said connection module to said second locking tab.

16. The combination according to claim 14, wherein said connection module includes:
a DIN rail with first and second flanges along its longitudinal edges; and
a plurality of connection units, each connection unit includes a first push-in receptacle in a front face of said connection unit to receive an end of an electrical wire of a first set, and includes a second push-in receptacle in said front face of said connection unit to receive an end of an electrical wire of a second set, each connection unit includes first and second guide channels formed on a rear face of said connection unit, wherein said first and second flanges of said DIN rail are slid into said first and second guide channels of said plurality of connection units to formed a stacked array of connection units on said DIN rail, and wherein said DIN rail is secured to both of said first and second locking tabs.

17. The combination according to claim 16, wherein said DIN rail is formed of steel and said first and second flanges are considered off-set flanges because said first and second flanges are not co-planar to a mid-section of said DIN rail.

18. The combination according to claim 14, further comprising:
jumper slots, test ports and/or labels provided in or on said front face of each connection unit between said first and second push-in receptacles; and
first and second end caps, each having first and second guide channels formed on a rear face thereof, wherein said first and second flanges of said DIN rail are also slid into said first and second guide channels of said first and second end caps.

19. The combination according to claim 18, further comprising:
first and second notches formed within said first longitudinal edge of said window formed in said mounting plate;
third and fourth notches formed within said second longitudinal edge of said window formed in said mounting plate;
first and second blades formed along top surfaces of said first and second end caps, which sit in said first and second notches, when said connection module resides within said window; and
third and fourth blades formed along bottom surfaces of said first and second end caps, which sit in said third and fourth notches, when said connection module resides within said window.

20. A combination of first and second network rail racks, a connection module and a mounting plate attached to said first and second network rack rails, said combination comprising:
a first network rack rail;
a second network rack rail;
a generally flat plate having a front face and a rear face, left and right side edges, a top edge and a bottom edge;
at least one first fastening feature formed on said plate proximate said left side edge attaching said left side edge to said first network rack rail;
at least one second fastening feature formed on said plate proximate said right side edge attaching said right side edge to said second network rack rail;
a window formed within said mounting plate, said window being defined within first and second longitudinal edges and first and second lateral edges formed within said front face;
a connection module located within said window having a rear portion of said connection module extending away from said rear face of said mounting plate to a first degree, and a front portion of said connection module being approximately flush with said front face of said mounting plate or extending away from said front face of said mounting plate to a second degree less than said first degree;
a first ear extending away from said rear face of said mounting plate;
a second ear extending away from said rear face of said mounting plate;
a first locking tab extending away from said first ear attached to said connection module; and
a second locking tab extending away from said second ear for attached to said connection module.
